(19) United States
(12) Patent Application Publication
(10) Pub. No.: US 2026/0297750 A1
(43) Pub. Date: Oct. 1, 2026

(54) SUBSTRATE STAGE AND SUBSTRATE PROCESSING APPARATUS

(71) Applicant: Tokyo Electron Limited, Tokyo (JP)

(72) Inventors: Motoi YAMAGATA, Tokyo (JP); Haitang ZHANG, Tokyo (JP); Naoya FUKUDA, Tokyo (JP); Yuki MOTOMURA, Nirasaki City (JP)

(21) Appl. No.: 19/629,744

(22) Filed: Mar. 26, 2026

(30) Foreign Application Priority Data
Mar. 31, 2025 (JP) 2025-059219
Jan. 29, 2026 (JP) 2026-013518

(51) Int. Cl. C23C 16/458

(52) U.S. Cl. CPC C23C 16/4586; C23C 16/4584

(57) ABSTRACT

A substrate stage, including: a stage on which a substrate is placed; a stage support mechanism configured to support the stage; and a cooling mechanism configured to cool the stage, wherein the stage has a contact surface located on a rear surface of the stage and formed radially outward of a support portion of the stage supported by the stage support mechanism, and wherein the cooling mechanism includes: a cold link; a cooler configured to cool the cold link; and a heat transfer plate provided between the contact surface of the stage and the cold link.

### CROSS-REFERENCE TO RELATED APPLICATIONS

This application is based upon and claims the benefit of priority from Japanese Patent Application No. 2025-059219, filed on Mar. 31, 2025, and Japanese Patent Application No. 2026-013518, filed on Jan. 29, 2026, the entire contents of which are incorporated herein by reference.

### TECHNICAL FIELD

The present disclosure relates to a substrate stage and a substrate processing apparatus.

### BACKGROUND

Patent Document 1 discloses a substrate placement mechanism for placing a substrate on which a film is formed within a film formation apparatus, the substrate placement mechanism including: a stage having a substrate placement surface on which the substrate is placed; a cooling head provided to face a side of the stage opposite to the substrate placement surface and configured to be cooled to an extremely low temperature by a refrigerator; a contact/separation mechanism configured to cause the stage and the cooling head to be brought into contact with or separated from each other; a rotation mechanism configured to rotate the stage; a contact/separation structure which is provided between the stage and the cooling head, having a first member on a side of the stage and a second member on a side of the cooling head, wherein the first member and the second member being brought into contact with or separated from each other by the contact/separation mechanism; and a controller.

Patent Document 2 discloses a stage including a base having a base to which high-frequency power is supplied and an electrostatic chuck which is made of ceramic and has a clamping electrode in the electrostatic chuck.

### Prior Art Documents

### Patent Documents

Patent Document 1: Japanese Patent No. 7134039

Patent Document 2: Japanese Patent No. 7499651

### SUMMARY

According to one embodiment of the present disclosure, a substrate stage, includes a stage on which a substrate is placed, a stage support mechanism configured to support the stage, and a cooling mechanism configured to cool the stage, wherein the stage has a contact surface located on a rear surface of the stage and formed radially outward of a support portion of the stage supported by the stage support mechanism, and wherein the cooling mechanism includes a cold link, a cooler configured to cool the cold link, and a heat transfer plate provided between the contact surface of the stage and the cold link.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an exemplary cross-sectional view showing a configuration of a substrate stage according to a first embodiment during rotation.

FIG. 2 is an exemplary cross-sectional view showing a configuration of a substrate stage according to a first embodiment during cooling.

FIG. 3 is an exemplary cross-sectional view showing a configuration of a substrate stage according to a second embodiment during rotation.

FIG. 4 is an exemplary cross-sectional view showing a configuration of a substrate stage according to a second embodiment during cooling.

FIG. 5 is an exemplary cross-sectional view showing a configuration of a substrate stage according to a third embodiment during rotation.

FIG. 6 is an exemplary schematic cross-sectional view showing a configuration of an expansion and contraction portion.

FIG. 7 is an exemplary schematic cross-sectional view showing a configuration of an expansion and contraction portion.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments for carrying out the present disclosure will be described with reference to the accompanying drawings. In each drawing, the same or corresponding members or components will be denoted by the same or corresponding reference numerals, and redundant explanations thereof may be omitted.

### Substrate Stage According to First Embodiment

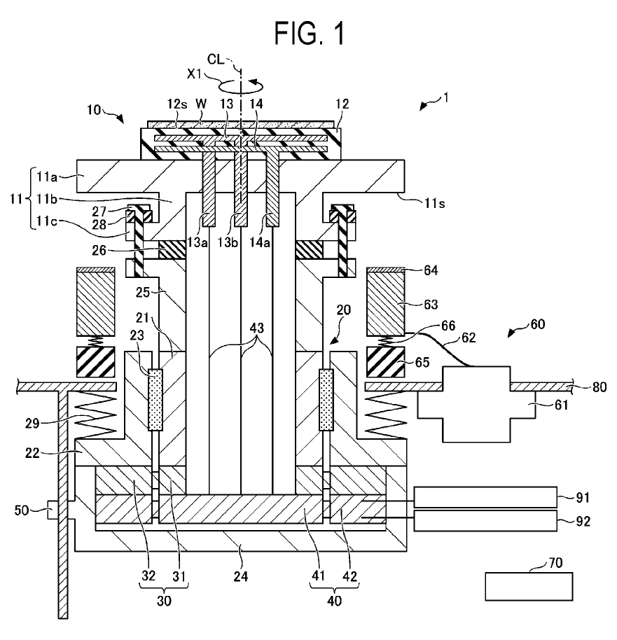

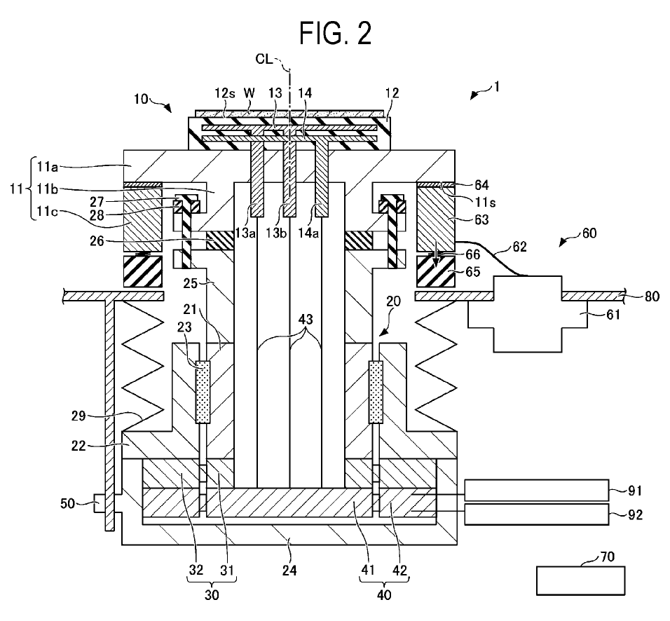

An example of a substrate stage 1 according to a first embodiment will be described with reference to FIGS. 1 and 2. FIG. 1 is an exemplary cross-sectional view showing the configuration of the substrate stage 1 according to the first embodiment during rotation. FIG. 2 is an exemplary cross-sectional view showing the configuration of the substrate stage 1 according to the first embodiment during cooling.

The substrate stage 1 includes a stage 10 on which a substrate W is placed, a rotation drive mechanism 20 that rotates the stage 10, an elevation drive mechanism 50 that raises and lowers the stage 10, a cooling mechanism 60 that cools the stage 10, and a controller 70.

Here, a substrate processing apparatus includes a processing container (in FIG. 1, a bottom wall 80 of the processing container is shown) and the substrate stage 1. The stage 10 is disposed in an internal space of the processing container (in FIG. 1, a space above the bottom wall 80 of the processing container) of the substrate processing apparatus. The processing container is configured such that the internal space of the processing container is depressurized to high vacuum by operating an exhauster (not shown) such as a vacuum pump.

Here, the substrate processing apparatus may be, for example, a substrate processing apparatus (e.g., a chemical vapor deposition (CVD) apparatus or an atomic layer deposition (ALD) apparatus) that supplies a process gas into the processing container to perform a desired process (e.g., a film formation process) on a substrate W. Alternatively, the substrate processing apparatus may be a substrate processing apparatus (e.g., a physical vapor deposition (PVD) apparatus) that supplies the process gas into the processing container and sputters a target provided in the processing container to perform the desired process (e.g., the film formation process) on the substrate W.

The stage 10 includes a base 11, an insulating layer 12, a chuck electrode 13, and a bias electrode 14.

The base 11 includes a plate 11a, a support portion 11b, and a flange 11c. The plate 11a is formed in a disc shape and is made of a material having high thermal conductivity (e.g., Cu). The support portion 11b is formed in a cylindrical shape and protrudes downward from a rear surface of the plate 11a. The flange 11c is formed in an annular shape to expand radially outward below the support portion 11b. The plate 11a, the support portion 11b, and the flange 11c of the base 11 may be formed integrally, or the base 11 may be configured by assembling separate members.

The base 11 also has a contact surface 11s that is thermally connected to a refrigerator 61 described later. The contact surface 11s is located on the rear surface of the plate 11a of the base 11 and is formed radially outward of the support portion 11b.

The insulating layer 12 made of a dielectric is provided on the base 11. The chuck electrode 13 and the bias electrode 14 are provided within the insulating layer 12. An upper surface of the insulating layer 12 serves as a placement surface 12s on which the substrate W is placed.

The chuck electrode 13 is provided within the insulating layer 12 and is located above the bias electrode 14. In other words, the chuck electrode 13 is provided closer to the placement surface 12s of the substrate W than the bias electrode 14.

A predetermined voltage (a clamping voltage) is applied to the chuck electrode 13 from a clamping-voltage power supply 91 via a slip ring 40 and a wiring 43, which will be described later. As a result, the substrate W placed on the placement surface 12s of the stage 10 is electrostatically clamped, and the substrate W can be fixed to the stage 10. In this way, the insulating layer 12 and the chuck electrode 13 constitute an electrostatic chuck.

The bias electrode 14 is provided within the insulating layer 12 and below the chuck electrode 13. In other words, the bias electrode 14 is provided farther from the placement surface 12s of the substrate W than the chuck electrode 13.

A predetermined voltage (a bias voltage) is applied to the bias electrode 14 from a bias-voltage power supply 92 via the slip ring 40 and the wiring 43, which will be described later. As a result, for example, in a substrate processing apparatus that generates plasma of a process gas in a processing container, ions generated from the plasma of the process gas can be drawn into the substrate W.

In a configuration in which the bias voltage is applied to the base 11, there is a concern that the structure of the stage 10 may become complicated due to an insulating structure for insulating the base 11. Therefore, by providing the bias electrode 14 within the insulating layer 12, the structure of the stage 10 can be simplified.

In a configuration in which the superimposed bias voltage is applied to the chuck electrode 13, it becomes difficult to apply a high-power bias voltage. Therefore, by providing the bias electrode 14 within the insulating layer 12, the high-power bias voltage can be applied to the bias electrode 14 while suppressing discharge.

Terminals 13a and 13b of the chuck electrode 13 and a terminal 14a of the bias electrode 14 are arranged on the rear surface of the plate 11a and are located inward of the cylindrical support portion 11b.

The stage 10 is rotatably supported by the rotation drive mechanism 20. The rotation drive mechanism 20 includes a rotation drive device 30, a rotation shaft 21, an upper housing 22, a magnetic fluid seal 23, a lower housing 24, a stand 25, a thermal insulator 26, a fastener 27, a thermal insulator 28, and a bellows 29.

The rotation drive device 30 is a direct-drive motor having a rotor 31 and a stator 32. The rotor 31 has a substantially cylindrical shape extending coaxially with the rotation shaft 21 and is fixed to the rotation shaft 21. The stator 32 has a substantially cylindrical shape with an inner diameter larger than an outer diameter of the rotor 31. The rotation drive device 30 may be a type other than the direct-drive motor and may be a type including a servo motor and a transmission belt.

The rotation shaft 21 has a substantially cylindrical shape extending coaxially with a central axis CL of the stage 10. The upper housing 22 is provided radially outward of the rotation shaft 21. The upper housing 22 has a substantially cylindrical shape extending coaxially with the central axis CL of the stage 10.

The magnetic fluid seal 23 is provided between an inner peripheral surface of the upper housing 22 and an outer circle of the rotation shaft 21. The magnetic fluid seal 23 rotatably supports the rotation shaft 21 with respect to the upper housing 22 and provides a seal between the inner peripheral surface of the upper housing 22 and the outer circle of the rotation shaft 21.

The lower housing 24 accommodates the rotation drive device 30 and the slip ring 40 in the lower housing 24. The lower housing 24 is fixed to the upper housing 22.

The slip ring 40 is provided below the rotation shaft 21 and the upper housing 22. The slip ring 40 includes a rotating body 41 including a metal ring and a fixed body 42 including a brush. The rotating body 41 has a substantially cylindrical shape extending coaxially with the rotation shaft 21 and is fixed to a lower surface of the rotation shaft 21. The fixed body 42 has a substantially cylindrical shape with an inner diameter slightly larger than an outer diameter of the rotating body 41 and is fixed to a lower surface of the upper housing 22.

The slip ring 40 is electrically connected to the clamping-voltage power supply 91 and supplies a clamping voltage supplied from the clamping-voltage power supply 91 to the terminals 13a and 13b of the chuck electrode 13 via the brush of the fixed body 42, the metal ring of the rotating body 41, and the wiring 43. The slip ring 40 is also electrically connected to the bias-voltage power supply 92 and supplies a bias voltage supplied from the bias-voltage power supply 92 to the terminal 14a of the bias electrode 14 via the brush of the fixed body 42, the metal ring of the rotating body 41, and the wiring 43. The slip ring 40 may have a structure other than the brush structure. For example, the slip ring 40 may have a non-contact power supply structure or a structure, which is mercury-free or has conductive liquid.

The stand 25 is provided between the rotation shaft 21 and the support portion 11b of the stage 10, and is configured such that the rotation of the rotation shaft 21 is transmitted to the stand 25. The thermal insulator 26 is disposed between the support portion 11b of the stage 10 and the stand 25. The support portion 11b of the stage 10 and the stand 25 are fixed by the fastener 27 such as a bolt. The thermal insulator 28 is disposed between a head of the fastener 27 and the support portion 11b of the stage 10. As the thermal insulator 26 and 28, resin members having low thermal conductivity, such as polyetherimide (PEI), polyetheretherketone (PEEK), and polyphenylene sulfide (PPS), or ceramic materials, such as Photoveel (registered trademark) and Macor (registered trademark), can be used.

The substantially cylindrical bellows 29 is provided between the upper housing 22 and the bottom wall 80 of the processing container. The bellows 29 has a metallic bellows structure that is expandable and contractible in a vertical direction. The bellows 29 allows the upper housing 22 to move in the vertical direction (axial direction of the central axis CL) with respect to the bottom wall 80 of the processing container and provides a seal between the upper housing 22 and the bottom wall 80 of the processing container. The bellows 29 may be formed of, for example, stainless steel such as SUS316L or AM350.

By the above configuration, when the rotor 31 of the rotation drive device 30 rotates, the rotation shaft 21, the stand 25, the thermal insulator 26, the fastener 27, the thermal insulator 28, and the stage 10 rotate in an X1 direction. The rotating body 41 of the slip ring 40 and the wiring 43 also rotate together with the stage 10. Further, the stator 32 of the rotation drive device 30, the fixed body 42 of the slip ring 40, and the upper housing 22 are fixed to the lower housing 24 and are configured not to rotate.

The lower housing 24 of the rotation drive mechanism 20 is supported to move vertically by the elevation drive mechanism 50. The elevation drive mechanism 50 raises and lowers the stage 10 by raising and lowering the rotation drive mechanism 20. Thus, as the stage 10 is raised by the elevation drive mechanism 50, the contact surface 11s of the stage 10 is separated from a cold link 63 (a heat transfer plate 64) of the cooling mechanism 60 (refer to FIG. 1). Further, as the stage 10 is lowered by the elevation drive mechanism 50, the contact surface 11s of the stage 10 comes into contact with the cold link 63 (the heat transfer plate 64) of the cooling mechanism 60 (refer to FIG. 2).

In this way, the substrate stage 1 can be switched between a first state in which the contact surface 11s of the stage 10 is separated from the cold link 63 (the heat transfer plate 64) of the cooling mechanism 60 and the stage 10 is rotatable (refer to FIG. 1) and a second state in which the contact surface 11s of the stage 10 is in contact with the cold link 63 (the heat transfer plate 64) of the cooling mechanism 60 to cool the stage 10 (refer to FIG. 2).

That is, the stage 10 is supported by a stage support mechanism. The stage support mechanism includes a hollow portion in which the terminals 13a and 13b of the chuck electrode 13, the terminal 14a of the bias electrode 14, and the wiring 43 (a power supply path) are arranged, a rotation driver (the rotation drive mechanism 20 and the rotation drive device 30) that rotates the stage 10, and an elevation driver (the elevation drive mechanism 50) that raises and lowers the stage 10.

The cooling mechanism 60 includes the refrigerator 61, a heat transfer member 62, the cold link 63, the heat transfer plate 64, a support member 65, and an elastic member 66.

The refrigerator 61 is thermally connected to the cold link 63 via the heat transfer member 62 and cools an upper surface of the cold link 63 to an extremely low temperature (e.g., -100 degrees C). From the viewpoint of cooling capacity, the refrigerator 61 is desirably of a type using a Gifford-McMahon (GM) cycle.

The heat transfer member 62 thermally connects the refrigerator 61 and the cold link 63. The heat transfer member 62 is formed of, for example, a copper foil or a cable and is configured to be capable of following vertical movement of the cold link 63 which is supported by the elastic member 66 described later.

Further, the refrigerator 61 and the heat transfer member 62 constitute a cooler that cools the cold link 63.

The cold link 63 is formed of a material having high thermal conductivity (e.g., Cu) and has a substantially annular outer shape. The heat transfer plate 64 is provided on an upper surface of the cold link 63.

The heat transfer plate 64 is formed of a soft, elastically deformable metal. In other words, the heat transfer plate 64 is formed of a soft metal that is more easily elastically deformable than a material of a lower surface of the stage 10 and/or a material of an upper surface of the cold link 63. In other words, the heat transfer plate 64 is formed of a metal having lower hardness (e.g., Vickers hardness) than the material of the lower surface of the stage 10 and/or the material of the upper surface of the cold link 63. The heat transfer plate 64 can be used in a vacuum atmosphere of an internal space and is made of a material that can also be used at an extremely low temperature cooled by the refrigerator 61. The heat transfer plate 64 is also made of a material that does not affect a substrate processing process. A material having high thermal conductivity is desirable for the heat transfer plate 64. The material of the heat transfer plate 64 may have lower thermal conductivity than the material of the lower surface of the stage 10 and/or the material of the upper surface of the cold link 63. Specifically, as the soft metal, indium, silver, or tin can be used. The heat transfer plate 64 is formed as a sheet-like member (a soft metal sheet, for example, an indium sheet). Accordingly, even when the material of the heat transfer plate 64 has lower thermal conductivity than the material of the lower surface of the stage 10 and/or the material of the upper surface of the cold link 63, the influence on overall heat conduction from the refrigerator 61 to the stage 10 can be sufficiently reduced by forming the heat transfer plate 64 as a thin sheet-like member.

The cold link 63 is supported by the support member 65 via the elastic member 66. The support member 65 and/or the elastic member 66 are desirably made of a thermal insulating material. As shown in FIG. 2, the stage 10 and the rotation drive mechanism 20 are lowered by the elevation drive mechanism 50 so that the contact surface 11s of the stage 10 comes into contact with the cold link 63 (the heat transfer plate 64). In this case, the elastic member 66 is compressively deformed. By the compressive deformation of the elastic member 66, load on the magnetic fluid seal 23 is reduced. Furthermore, deterioration of the sealing performance of the magnetic fluid seal 23 is prevented.

The controller 70 is, for example, a computer and includes a central processing unit (CPU), a random access memory (RAM), a read only memory (ROM), and an auxiliary storage device. The CPU operates based on computer readable programs stored in the ROM or the auxiliary storage device (non-transitory) and controls operation of the substrate processing apparatus including the substrate stage 1. The controller 70 may be provided inside the substrate processing apparatus or may be provided outside the substrate processing apparatus. When the controller 70 is provided outside the substrate processing apparatus, the controller 70 can control the substrate processing apparatus via a wired or wireless communication means.

When performing a desired substrate processing process (e.g., a film formation process) on the substrate W, the controller 70 controls, as shown in FIG. 1, the elevation drive mechanism 50 to separate the contact surface 11s of the stage 10 from the cold link 63 (the heat transfer plate 64) and controls the rotation drive mechanism 20 (the rotation drive device 30) to rotate the stage 10 on which the substrate W is placed. As a result, in-plane uniformity of the substrate processing process (e.g., the film formation process) of the substrate W can be improved.

When cooling the stage 10 and the substrate W placed on the stage 10, the controller 70 stops, as shown in FIG. 2, the rotation drive mechanism 20 (the rotation drive device 30) to stop rotation of the stage 10 and controls the elevation drive mechanism 50 to bring the contact surface 11s of the stage 10 into contact with the cold link 63 (the heat transfer plate 64). As a result, the cold link 63 and the stage 10 are thermally connected via the heat transfer plate 64, so that the substrate W placed on the stage 10 can be cooled.

Here, the heat transfer plate 64 elastically deforms so as to conform to surface roughness of the upper surface of the cold link 63 and the contact surface 11s of the stage 10. As a result, a contact area between an upper surface of the heat transfer plate 64 and the contact surface 11s of the stage 10 increases. In addition, a contact area between a lower surface of the heat transfer plate 64 and the upper surface of the cold link 63 increases. As a result, thermal resistance at a contact portion between the stage 10 and the cold link 63 can be reduced. Therefore, cooling performance of the stage by the refrigerator 61 is improved.

In addition, the substrate stage 1 requires a mechanism for rotating the stage 10, a mechanism for raising and lowering the stage 10, and a mechanism for switching between contact and non-contact between the stage 10 and the cooling mechanism 60. In the substrate stage 1, the rotation drive mechanism 20 can serve as the mechanism for rotating the stage 10. Further, in the substrate stage 1, the single elevation drive mechanism 50 may serve as both the mechanism for raising and lowering the stage 10 and the mechanism for switching between contact and non-contact between the stage 10 and the cooling mechanism 60. As a result, the number of elevation drive mechanisms can be reduced.

In addition, by arranging the cold link 63 in an annular shape outward of the support portion 11b of the base 11, interiors of the support portion 11b, the stand 25, and the rotation shaft 21 can be formed as a hollow portion, and the terminals 13a and 13b of the chuck electrode 13, the terminal 14a of the bias electrode 14, the wiring 43, and the like can be arranged in the hollow portion. A seal is provided between a space of the hollow portion and a processing space inside the processing container (a space depressurized to high vacuum). As a result, even when a high-power bias voltage is applied to the bias electrode 14, occurrence of discharge at the terminal 14a of the bias electrode 14 is prevented. In addition, in the space of the hollow portion, a gas pipe (not shown) that supplies a heat transfer gas (He gas) supplied between a rear surface of the substrate W and the placement surface 12s of the stage 10, or other devices, can be arranged.

Further, as compared with a configuration in which the cold link is brought into contact with the center of a rear surface of a stage, diameters of the support portion 11b, the stand 25, and the rotation shaft 21 can be reduced, and diameters of the magnetic fluid seal 23, the bellows 29, the rotation drive device 30, and the slip ring 40 can also be reduced.

Further, by reducing the diameter of the magnetic fluid seal 23, a driving force required for the rotation drive device 30 can be reduced. As a result, the rotation drive device 30 can be reduced in size and weight.

In addition, by reducing the diameter of the bellows 29, a driving force required for the elevation drive mechanism 50 can be reduced. Further, by reducing the weight of the rotation drive device 30 raised and lowered by the elevation drive mechanism 50, the driving force required for the elevation drive mechanism 50 can also be reduced. As a result, the elevation drive mechanism 50 can be reduced in size and weight.

### Substrate Stage According to Second Embodiment

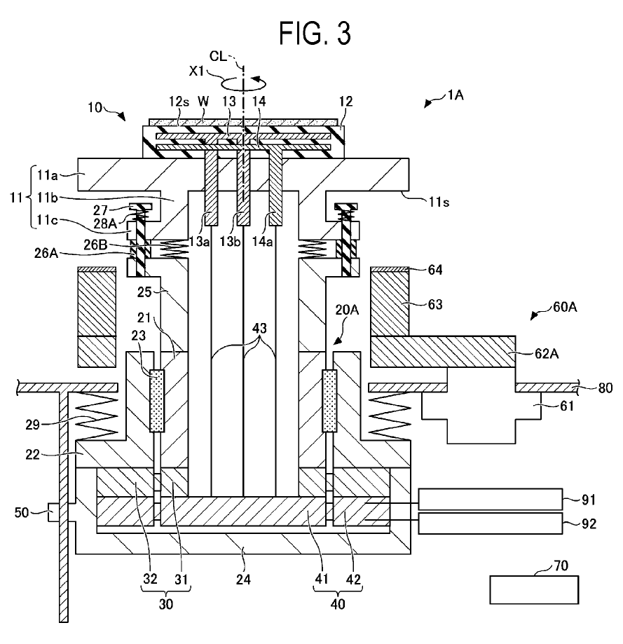

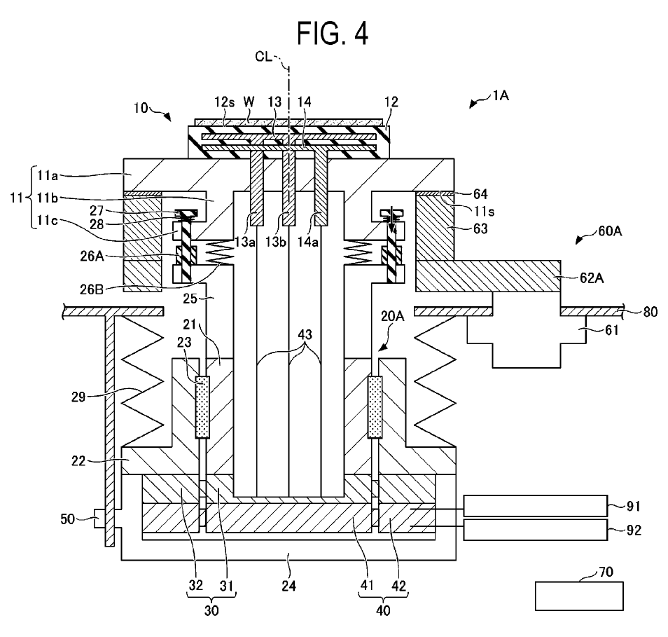

An example of a substrate stage 1A according to a second embodiment will now be described with reference to FIGS. 3 and 4. FIG. 3 is an exemplary cross-sectional view showing a configuration of the substrate stage 1A according to the second embodiment during rotation. FIG. 4 is an exemplary cross-sectional view showing a configuration of the substrate stage 1A according to the second embodiment during cooling.

The substrate stage 1A includes a stage 10 on which a substrate W is placed, a rotation drive mechanism 20A that rotates the stage 10, an elevation drive mechanism 50 that raises and lowers the stage 10, a cooling mechanism 60A that cools the stage 10, and a controller 70.

Here, the substrate stage 1A according to the second embodiment (refer to FIGS. 3 and 4) differs from the substrate stage 1 according to the first embodiment (refer to FIGS. 1 and 2) in the configurations of the rotation drive mechanism 20A and the cooling mechanism 60A. Other configurations are the same, and redundant descriptions thereof are therefore omitted.

The rotation drive mechanism 20A includes a rotation drive device 30, a rotation shaft 21, an upper housing 22, a magnetic fluid seal 23, a lower housing 24, a stand 25, a thermal insulator 26A, a bellows 26B, a fastener 27, an elastic member 28A, and a bellows 29. The thermal insulator 26A and the substantially cylindrical bellows 26B are disposed between a support portion 11b of the stage 10 and the stand 25. The support portion 11b of the stage 10 and the stand 25 are fixed by the fastener 27 such as a bolt. The elastic member 28A is disposed between a head of the fastener 27 and the support portion 11b of the stage 10. Other configurations are the same, and redundant descriptions thereof are therefore omitted.

The cooling mechanism 60A includes a refrigerator 61, a heat transfer member 62A, a cold link 63, and a heat transfer plate 64. The heat transfer member 62A is thermally connected to the refrigerator 61 and the cold link 63. The heat transfer member 62A is formed of a thick member and supports the cold link 63. Other configurations are the same, and redundant descriptions thereof are therefore omitted. Further, the refrigerator 61 and the heat transfer member 62A constitute a cooler that cools the cold link 63.

When performing a desired substrate processing process (e.g., a film formation process) on the substrate W, the controller 70 controls, as shown in FIG. 3, the elevation drive mechanism 50 to separate a contact surface 11s of the stage 10 from the cold link 63 (the heat transfer plate 64) and controls the rotation drive mechanism 20A (the rotation drive device 30) to rotate the stage 10 on which the substrate W is placed. As a result, in-plane uniformity of the substrate processing process (e.g., the film formation process) of the substrate W can be improved.

Here, due to the pressing force of the elastic member 28A, a flange 11c of the stage 10 is pressed toward the stand 25 and comes into contact with the thermal insulator 26A.

When cooling the stage 10 and the substrate W placed on the stage 10, the controller 70 stops, as shown in FIG. 4, the rotation drive mechanism 20A (the rotation drive device 30) to stop rotation of the stage 10 and controls the elevation drive mechanism 50 to bring the contact surface 11s of the stage 10 into contact with the cold link 63 (the heat transfer plate 64). As a result, the cold link 63 and the stage 10 are thermally connected via the heat transfer plate 64, so that the substrate W placed on the stage 10 can be cooled.

Here, the elastic member 28A is compressively deformed, and the flange 11c of the stage 10 is separated from the thermal insulator 26A. In addition, compression deformation of the elastic member 28A reduces load on the magnetic fluid seal 23. Furthermore, deterioration of the sealing performance of the magnetic fluid seal 23 is prevented.

In addition, the heat transfer plate 64 elastically deforms so as to conform to the surface roughness of an upper surface of the cold link 63 and the contact surface 11s of the stage 10. As a result, a contact area between an upper surface of the heat transfer plate 64 and the contact surface 11s of the stage 10 increases. In addition, a contact area between a lower surface of the heat transfer plate 64 and the upper surface of the cold link 63 increases. As a result, thermal resistance at a contact portion between the stage 10 and the cold link 63 can be reduced. Therefore, cooling performance of the stage 10 by the refrigerator 61 is improved.

In addition, the substrate stage 1A requires a mechanism for rotating the stage 10, a mechanism for raising and lowering the stage 10, and a mechanism for switching between contact and non-contact between the stage 10 and the cooling mechanism 60. In the substrate stage 1A, the rotation drive mechanism 20A can serve as the mechanism for rotating the stage 10. Further, in the substrate stage 1A, the single elevation drive mechanism 50 can serve as both the mechanism for raising and lowering the stage 10 and the mechanism for switching between contact and non-contact between the stage 10 and the cooling mechanism 60. As a result, the number of elevation drive mechanisms can be reduced.

In addition, by arranging the cold link 63 in an annular shape outward of the support portion 11b of the base 11, interiors of the support portion 11b, the stand 25, and the rotation shaft 21 can be formed as a hollow portion, and terminals 13a and 13b of the chuck electrode 13, a terminal 14a of the bias electrode 14, a wiring 43, and the like can be arranged in the hollow portion. A seal is provided between a space of the hollow portion and a processing space inside the processing container (a space depressurized to high vacuum) by the bellows 26B. As a result, even when a high-power bias voltage is applied to the bias electrode 14, occurrence of discharge at the terminal 14a of the bias electrode 14 is prevented. In addition, in the space of the hollow portion, a gas pipe (not shown) that supplies a heat transfer gas (He gas or the like) between a rear surface of the substrate W and the placement surface 12s of the stage 10, or other devices, can be arranged.

Further, as compared with a configuration in which the cold link is brought into contact with the center of a rear surface of a stage, diameters of the support portion 11b, the stand 25, and the rotation shaft 21 can be reduced, and diameters of the magnetic fluid seal 23, the bellows 29, the rotation drive device 30, and the slip ring 40 can also be reduced.

Further, by reducing the diameter of the magnetic fluid seal 23, a driving force required for the rotation drive device 30 can be reduced. As a result, the rotation drive device 30 can be reduced in size and weight.

In addition, by reducing the diameter of the bellows 29, a driving force required for the elevation drive mechanism 50 can be reduced. Further, by reducing the weight of the rotation drive device 30 raised and lowered by the elevation drive mechanism 50, the driving force required for the elevation drive mechanism 50 can also be reduced. As a result, the elevation drive mechanism 50 can be reduced in size and weight.

### Substrate Stage According to Third Embodiment

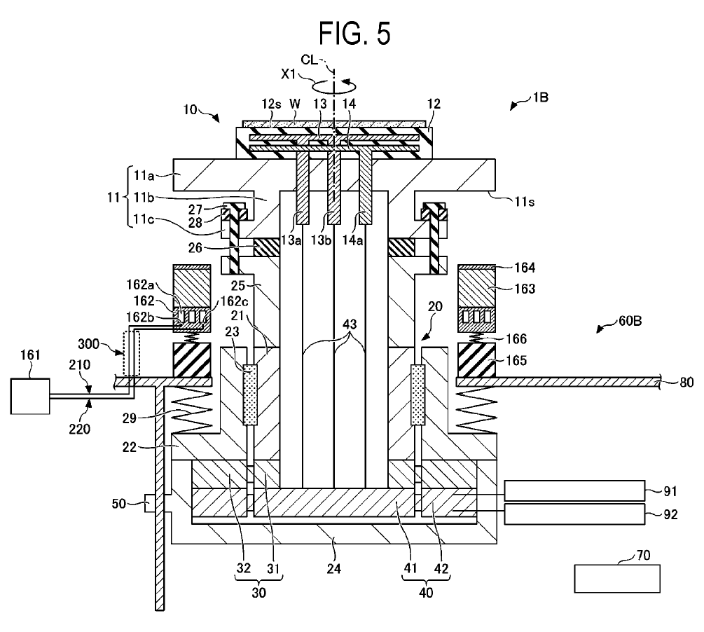

An example of a substrate stage 1B according to a third embodiment will now be described with reference to FIG. 5. FIG. 5 is an exemplary cross-sectional view showing a configuration of the substrate stage 1B according to the third embodiment during rotation.

The substrate stage 1B includes a stage 10 on which a substrate W is placed, a rotation drive mechanism 20 that rotates the stage 10, an elevation drive mechanism 50 that raises and lowers the stage 10, a cooling mechanism 60B that cools the stage 10, and a controller 70.

Here, the substrate stage 1B according to the third embodiment differs from the substrate stage 1 according to the first embodiment (see FIGS. 1 and 2) in a configuration of the cooling mechanism 60B. Other configurations are the same, and redundant description thereof is therefore omitted.

The cooling mechanism 60B includes a chiller 161, a cooling member 162, a cold link 163, a heat transfer plate 164, a support member 165, and an elastic member 166.

The chiller 161 cools a coolant to a predetermined temperature (e.g., -20 degrees C) and supplies the cooled coolant. As the coolant, brine or the like can be used.

The cooling member 162 is formed of a material having high thermal conductivity (e.g., Cu or Al) and has a substantially annular outer shape. The cooling member 162 includes a coolant flow path 162a in the cooling member 162. The coolant flow path 162a includes a flow path inlet 162b and a flow path outlet 162c. A discharge port of the chiller 161 and the flow path inlet 162b are connected to each other by a coolant introduction flow path 210. The flow path outlet 162c and an inlet port of the chiller 161 are connected to each other by a coolant discharge flow path 220. The coolant supplied from the chiller 161 circulates via the coolant introduction flow path 210, the flow path inlet 162b, the coolant flow path 162a, the flow path outlet 162c, and the coolant discharge flow path 220. Accordingly, the cooling member 162 is cooled. The cooling member 162 is thermally connected to the cold link 163.

The chiller 161, the cooling member 162, the coolant introduction flow path 210, and the coolant discharge flow path 220 constitute a cooler that cools the cold link 163.

The cold link 163 is formed of a material having high thermal conductivity (e.g., Cu), and has a substantially annular outer shape. The heat transfer plate 164 is provided on an upper surface of the cold link 163.

The heat transfer plate 164 is formed of a soft, elastically deformable metal. In other words, the heat transfer plate 164 is formed of a soft metal that is more easily elastically deformable than a material of a lower surface of the stage 10 and/or a material of the upper surface of the cold link 163. In other words, the heat transfer plate 164 is formed of a metal having lower hardness (e.g., Vickers hardness) than the material of the lower surface of the stage 10 and/or the material of the upper surface of the cold link 163. The heat transfer plate 164 is made of a material that can be used in a vacuum atmosphere of an internal space and that can also be used at a temperature cooled by the coolant supplied from the chiller 161. The heat transfer plate 164 is also made of a material that does not affect a substrate processing process. Further, the heat transfer plate 164 is desirably made of a material having high thermal conductivity. The material of the heat transfer plate 164 may have lower thermal conductivity than the material of the lower surface of the stage 10 and/or the material of the upper surface of the cold link 163. Specifically, as the soft metal, indium, silver, or tin can be used. In addition, the heat transfer plate 164 is formed as a sheet-like member (a soft metal sheet, for example, an indium sheet). Accordingly, even when the material of the heat transfer plate 164 has lower thermal conductivity than the material of the lower surface of the stage 10 and/or the material of the upper surface of the cold link 163, the influence on overall heat conduction from the cooling member 162 to the stage 10 can be sufficiently reduced by forming the heat transfer plate 164 as a thin sheet-like member.

The cold link 163 is supported by the support member 165 via the elastic member 166. The support member 165 and/or the elastic member 166 is desirably made of a thermal insulating material. The stage 10 and the rotation drive mechanism 20 are lowered by the elevation drive mechanism 50, so that a contact surface 11s of the stage 10 comes into contact with the cold link 163 (the heat transfer plate 164). In this case, the elastic member 166 is compressively deformed. By the compressive deformation of the elastic member 166, load applied to a magnetic fluid seal 23 is reduced. Further, deterioration of the sealing performance of the magnetic fluid seal 23 is prevented.

Here, the cooling member 162 and the cold link 163 are supported by the elastic member 166. By the compressive deformation of the elastic member 166, a height position of the cooling member 162 (a distance in a height direction from a bottom wall 80 to the cooling member 162) changes. Therefore, the coolant introduction flow path 210 and the coolant discharge flow path 220 are provided with an expansion and contraction portion 300 (300A and 300B) for accommodating a change in the position of the cooling member 162 and the cold link 163 in the height direction.

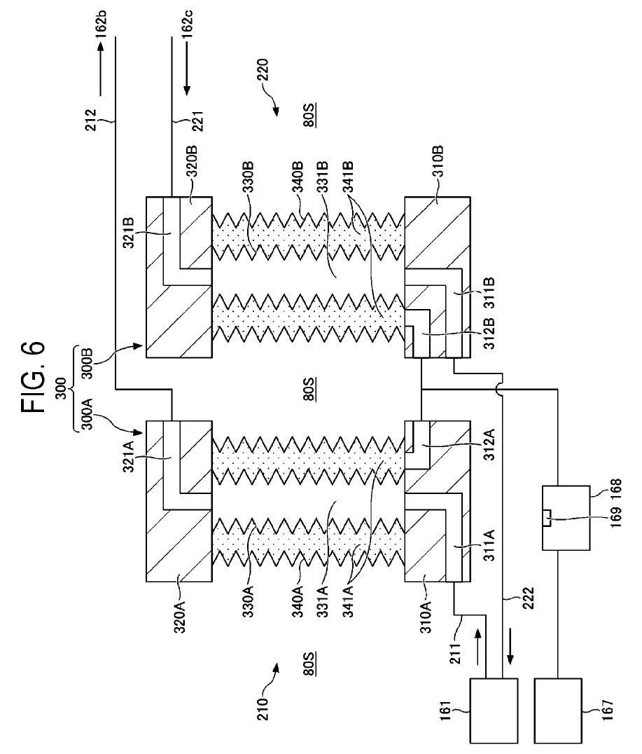

Next, the coolant introduction flow path 210 and the coolant discharge flow path 220 that include the expansion and contraction portion 300 will be described with reference to FIG. 6. FIG. 6 is an exemplary schematic cross-sectional view showing a configuration of the expansion and contraction portion 300. The expansion and contraction portion 300 shown in FIG. 6 includes an expansion and contraction portion 300A and an expansion and contraction portion 300B.

The coolant introduction flow path 210 connects the discharge port of the chiller 161 and the flow path inlet 162b so as to allow the coolant to flow therethrough. The coolant introduction flow path 210 includes a first coolant introduction pipe 211, the expansion and contraction portion 300A, and a second coolant introduction pipe 212.

One end of the first coolant introduction pipe 211 is connected to the discharge port of the chiller 161 so as to allow the coolant to flow therethrough, and the other end of the first coolant introduction pipe 211 is connected to the expansion and contraction portion 300A so as to allow the coolant to flow therethrough. The first coolant introduction pipe 211 is fixed to a side of the bottom wall 80. In the present disclosure, the phrase "fixed to a side of a target member or a structure" refers to a state in which an object is installed directly or indirectly on a specific side or position of the target member or the structure and movement or separation of the object is restricted. Specifically, the phrase means that the object is securely fixed in a vicinity of the target member using means such as screws, adhesives, welding, or fitting.

One end of the second coolant introduction pipe 212 is connected to the expansion and contraction portion 300A so as to allow the coolant to flow therethrough, and the other end of the second coolant introduction pipe 212 is connected to the flow path inlet 162b so as to allow the coolant to flow therethrough. The second coolant introduction pipe 212 is fixed to a side of the cooling member 162.

The expansion and contraction portion 300A is connected between the first coolant introduction pipe 211 and the second coolant introduction pipe 212 so as to allow the coolant to flow therethrough.

The coolant discharge flow path 220 connects the flow path outlet 162c and the inlet port of the chiller 161 so as to allow the coolant to flow therethrough. The coolant discharge flow path 220 includes a first coolant discharge pipe 221, the expansion and contraction portion 300B, and a second coolant discharge pipe 222.

One end of the first coolant discharge pipe 221 is connected to the flow path outlet 162c so as to allow the coolant to flow therethrough, and the other end of the first coolant discharge pipe 221 is connected to the expansion and contraction portion 300B so as to allow the coolant to flow therethrough. The first coolant discharge pipe 221 is fixed to the side of the cooling member 162.

One end of the second coolant discharge pipe 222 is connected to the expansion and contraction portion 300B so as to allow the coolant to flow therethrough, and the other end of the second coolant discharge pipe 222 is connected to the inlet port of the chiller 161 so as to allow the coolant to flow therethrough. The second coolant discharge pipe 222 is fixed to the side of the bottom wall 80.

The expansion and contraction portion 300B is connected between the first coolant discharge pipe 221 and the second coolant discharge pipe 222 so as to allow the coolant to flow therethrough.

The expansion and contraction portion 300A includes a first member 310A, a second member 320A, a first bellows 330A, and a second bellows 340A.

The first member 310A includes a coolant flow path 311A and a gas flow path 312A. The second member 320A includes a coolant flow path 321A. The first member 310A is fixed to the side of the bottom wall 80. The second member 320A is fixed to a side of the cooling member 162. That is, as the cooling member 162 and the cold link 163, which are supported by the elastic member 166, move up and down, a distance between the first member 310A and the second member 320A changes.

The first bellows 330A has a tubular shape and is configured to be expandable and contractible. One end of the first bellows 330A is hermetically connected to the first member 310A by welding or the like, and the other end of the first bellows 330A is hermetically connected to the second member 320A by welding or the like. An internal space 331A of the first bellows 330A is connected to the coolant flow path 311A so as to allow the coolant to flow therethrough. Further, the internal space 331A of the first bellows 330A is connected to the coolant flow path 321A so as to allow the coolant to flow therethrough. The first coolant introduction pipe 211 is connected to the coolant flow path 311A so as to allow the coolant to flow therethrough. The second coolant introduction pipe 212 is connected to the coolant flow path 321A so as to allow the coolant to flow therethrough.

Accordingly, the coolant supplied from the discharge port of the chiller 161 is supplied to the flow path inlet 162b via the first coolant introduction pipe 211, the coolant flow path 311A, the internal space 331A of the first bellows 330A, the coolant flow path 321A, and the second coolant introduction pipe 212.

The second bellows 340A is disposed outside the first bellows 330A. The second bellows 340A has a tubular shape and is configured to be expandable and contractible. One end of the second bellows 340A is hermetically connected to the first member 310A by welding or the like and the other end of the second bellows 340A is hermetically connected to the second member 320A by welding or the like. An internal space 341A located inside the second bellows 340A and outside the first bellows 330A is connected to the gas flow path 312A so as to allow a gas to flow therethrough.

A dry air supply source 167 fills the internal space 341A with dry air via the gas flow path 312A. In FIG. 6, the internal space 341A filled with dry air is shown with dot hatching. Further, a pressure detection chamber 168 having a pressure sensor 169 is provided between the dry air supply source 167 and the gas flow path 312A. The pressure sensor 169 detects pressure of the internal space 341A by detecting pressure inside the pressure detection chamber 168.

The coolant flows through the internal space 331A of the first bellows 330A. The internal space 341A located outside the first bellows 330A and inside the second bellows 340A is filled with dry air. An outside of the second bellows 340A corresponds to an internal space 80S of a processing container including the bottom wall 80 and is under vacuum.

Similarly, the expansion and contraction portion 300B includes a first member 310B, a second member 320B, a first bellows 330B, and a second bellows 340B.

The first member 310B includes a coolant flow path 311B and a gas flow path 312B. The second member 320B includes a coolant flow path 321B. The first member 310B is fixed to the side of the bottom wall 80. The second member 320B is fixed to the side of the cooling member 162. That is, as the cooling member 162 and the cold link 163, which are supported by the elastic member 166, move up and down, a distance between the first member 310B and the second member 320B changes.

The first bellows 330B has a tubular shape and is configured to be expandable and contractible. One end of the first bellows 330B is hermetically connected to the first member 310B by welding or the like, and the other end of the first bellows 330B is hermetically connected to the second member 320B by welding or the like. An internal space 331B of the first bellows 330B is connected to the coolant flow path 311B so as to allow the coolant to flow therethrough. Further, the internal space 331B of the first bellows 330B is connected to the coolant flow path 321B so as to allow the coolant to flow therethrough. The first coolant discharge pipe 221 is connected to the coolant flow path 321B so as to allow the coolant to flow therethrough. The second coolant discharge pipe 222 is connected to the coolant flow path 311B so as to allow the coolant to flow therethrough.

Accordingly, the coolant discharged from the flow path outlet 162c is supplied to the inlet port of the chiller 161 via the first coolant discharge pipe 221, the coolant flow path 321B, the internal space 331B of the first bellows 330B, the coolant flow path 311B, and the second coolant discharge pipe 222.

The second bellows 340B is disposed outside the first bellows 330B. The second bellows 340B has a tubular shape and is configured to be expandable and contractible. One end of the second bellows 340B is hermetically connected to the first member 310B by welding or the like and the other end of the second bellows 340B is hermetically connected to the second member 320B by welding or the like. An internal space 341B located inside the second bellows 340B and outside the first bellows 330B, is connected to the gas flow path 312B so as to allow a gas to flow therethrough.

The dry air supply source 167 fills the internal space 341B with dry air via the gas flow path 312B. In FIG. 6, the internal space 341B filled with dry air is shown with dot hatching. Further, the pressure detection chamber 168 having the pressure sensor 169 is provided between the dry air supply source 167 and the gas flow path 312B. The pressure sensor 169 detects pressure of the internal space 341B by detecting pressure inside the pressure detection chamber 168.

The coolant flows through the internal space 331B of the first bellows 330B. The internal space 341B located outside the first bellows 330B and inside the second bellows 340B is filled with dry air. An outside of the second bellows 340B corresponds to the internal space 80S of the processing container including the bottom wall 80 and is under vacuum.

While, in the example shown in FIG. 6, the dry air supply source 167, the pressure detection chamber 168, and the pressure sensor 169 are illustrated as being shared between the internal space 341A of the expansion and contraction portion 300A and the internal space 341B of the expansion and contraction portion 300B, the present disclosure is not limited thereto. Separate dry air supply sources 167, pressure detection chambers 168, and pressure sensors 169 may be provided for the internal space 341A of the expansion and contraction portion 300A and the internal space 341B of the expansion and contraction portion 300B, respectively.

As described above, since the expansion and contraction portion 300 (300A and 300B) is installed in the coolant introduction flow path 210 and the coolant discharge flow path 220, the bellows 330A, 340A, 330B, and 340B can be deformed in response to vertical movement of the cooling member 162 supported by the elastic member 166. Accordingly, the cooling member 162 and the cold link 163 can be cooled by circulating the coolant between the chiller 161 and the coolant flow path 162a.

Further, there is a concern that the bellows 330A, 340A, 330B, and 340B of the expansion and contraction portions 300 (300A and 300B) may be damaged due to repeated expansion and contraction.

Here, when the first bellows 330A of the expansion and contraction portion 300A is damaged, the coolant flowing through the internal space 331A leaks into the internal space 341A of the second bellows 340A and then flows into the pressure detection chamber 168 via the gas flow path 312B. Accordingly, leakage of the coolant into the internal space 80S of the processing container can be prevented.

Similarly, even when the first bellows 330B of the expansion and contraction portion 300B is damaged, the coolant can be prevented from leaking into the internal space 80S of the processing container.

Further, the controller 70 detects pressure of the pressure detection chamber 168 using the pressure sensor 169. Here, damage occurs in the first bellows 330A and/or the first bellows 330B, the coolant flowing through the internal space 331A and/or the internal space 331B leaks into the internal space 341A and/or the internal space 341B, so that the pressure detected by the pressure sensor 169 changes. For example, the pressure detected by the pressure sensor 169 increases. The controller 70 can detect damage to the first bellows 330A and/or the first bellows 330B by detecting a change (e.g., an increase) in the pressure detected by the pressure sensor 169.

Further, when the second bellows 340A of the expansion and contraction portion 300A is damaged, dry air in the internal space 341A leaks into the internal space 80S of the processing container. Meanwhile, the first bellows 330A is not damaged, and the coolant flowing through the internal space 331A can be prevented from leaking into the internal space 80S of the processing container.

Similarly, even when the second bellows 340B of the expansion and contraction portion 300B is damaged, the coolant may be prevented from leaking into the internal space 80S of the processing container.

Further, the controller 70 detects the pressure of the pressure detection chamber 168 using the pressure sensor 169. Here, damage occurs in the second bellows 340A and/or the second bellows 340B, dry air with which the internal space 341A and/or the internal space 341B is filled leaks into the internal space 80S of the processing container, so that the pressure detected by the pressure sensor 169 changes. For example, the pressure detected by the pressure sensor 169 decreases. The controller 70 can detect damage to the second bellows 340A and/or the second bellows 340B by detecting a change (e.g., a decrease) in the pressure detected by the pressure sensor 169.

Although the expansion and contraction portion 300 shown in FIG. 6 has been described by way of example as a configuration in which the expansion and contraction portion 300A of the coolant introduction flow path 210 and the expansion and contraction portion 300B of the coolant discharge flow path 220 are provided as separate bodies, the present disclosure is not limited thereto.

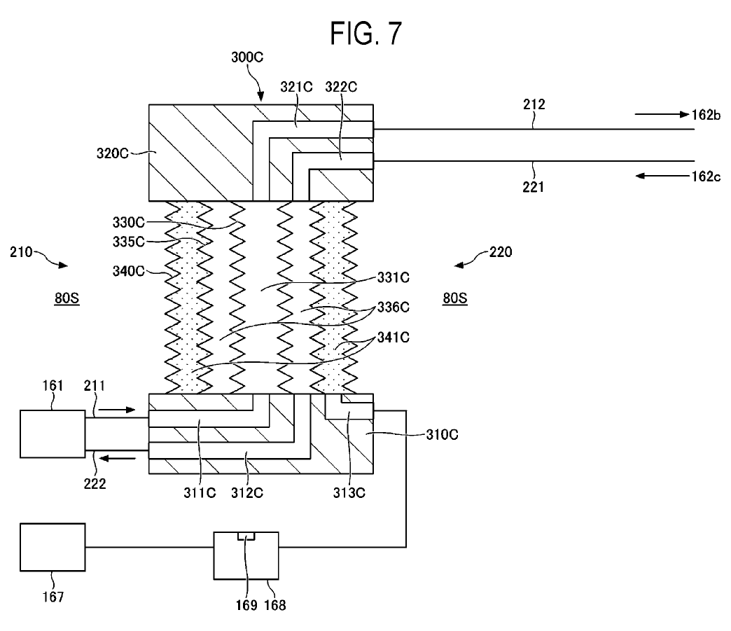

Next, the coolant introduction flow path 210 and the coolant discharge flow path 220 including an expansion and contraction portion 300C will be described with reference to FIG. 7. FIG. 7 is an exemplary schematic cross-sectional view for explaining a configuration of the expansion and contraction portion 300C.

The coolant introduction flow path 210 connects the discharge port of the chiller 161 and the flow path inlet 162b so as to allow the coolant to flow therethrough. The coolant introduction flow path 210 includes the first coolant introduction pipe 211, the expansion and contraction portion 300C, and the second coolant introduction pipe 212.

One end of the first coolant introduction pipe 211 is connected to the discharge port of the chiller 161 so as to allow the coolant to flow therethrough, and the other end of the first coolant introduction pipe 211 is connected to the expansion and contraction portion 300C so as to allow the coolant to flow therethrough. The first coolant introduction pipe 211 is fixed to the side of the bottom wall 80.

One end of the second coolant introduction pipe 212 is connected to the expansion and contraction portion 300C so as to allow the coolant to flow therethrough, and the other end of the second coolant introduction pipe 212 is connected to the flow path inlet 162b so as to allow the coolant to flow therethrough. The second coolant introduction pipe 212 is fixed to the side of the cooling member 162.

The expansion and contraction portion 300C is connected between the first coolant introduction pipe 211 and the second coolant introduction pipe 212 so as to allow the coolant to flow therethrough.

The coolant discharge flow path 220 connects the flow path outlet 162c and the inlet port of the chiller 161 so as to allow the coolant to flow therethrough. The coolant discharge flow path 220 includes the first coolant discharge pipe 221, the expansion and contraction portion 300C, and the second coolant discharge pipe 222.

One end of the first coolant discharge pipe 221 is connected to the flow path outlet 162c so as to allow the coolant to flow therethrough, and the other end of the first coolant discharge pipe 221 is connected to the expansion and contraction portion 300C so as to allow the coolant to flow therethrough. The first coolant discharge pipe 221 is fixed to the side of the cooling member 162.

One end of the second coolant discharge pipe 222 is connected to the expansion and contraction portion 300C so as to allow the coolant to flow therethrough, and the other end of the second coolant discharge pipe 222 is connected to the inlet port of the chiller 161 so as to allow the coolant to flow therethrough. The second coolant discharge pipe 222 is fixed to the side of the bottom wall 80.

The expansion and contraction portion 300C is connected between the first coolant discharge pipe 221 and the second coolant discharge pipe 222 so as to allow the coolant to flow therethrough.

The expansion and contraction portion 300C includes a first member 310C, a second member 320C, a first bellows 330C, a second bellows 335C, and a third bellows 340C.

The first member 310C includes a coolant flow path 311C, a coolant flow path 312C, and a gas flow path 313C. The second member 320C includes a coolant flow path 321C and a coolant flow path 322C. The first member 310C is fixed to the side of the bottom wall 80, and the second member 320C is fixed to the side of the cooling member 162. That is, as the cooling member 162 and the cold link 163, which are supported by the elastic member 166, move vertically, a distance between the first member 310C and the second member 320C changes.

The first bellows 330C has a tubular shape and is configured to be expandable and contractible. One end of the first bellows 330C is hermetically connected to the first member 310C by welding or the like, and the other end of the first bellows 330C is hermetically connected to the second member 320C by welding or the like. An internal space 331C of the first bellows 330C is connected to the coolant flow path 311C so as to allow the coolant to flow therethrough. The internal space 331C of the first bellows 330C is also connected to the coolant flow path 321C so as to allow the coolant to flow therethrough. The first coolant introduction pipe 211 is connected to the coolant flow path 311C so as to allow the coolant to flow therethrough. The second coolant introduction pipe 212 is connected to the coolant flow path 321C so as to allow the coolant to flow therethrough.

Accordingly, the coolant supplied from the discharge port of the chiller 161 is supplied to the flow path inlet 162b via the first coolant introduction pipe 211, the coolant flow path 311C, the internal space 331C of the first bellows 330C, the coolant flow path 321C, and the second coolant introduction pipe 212.

The second bellows 335C is disposed on the outer side of the first bellows 330C. The second bellows 335C has a tubular shape and is configured to be expandable and contractible. One end of the second bellows 335C is hermetically connected to the first member 310C by welding or the like, and the other end of the second bellows 335C is hermetically connected to the second member 320C by welding or the like. An internal space 336C of the second bellows 335C is connected to the coolant flow path 312C so as to allow the coolant to flow therethrough. The internal space 336C of the second bellows 335C is also connected to the coolant flow path 322C so as to allow the coolant to flow therethrough. The first coolant discharge pipe 221 is connected to the coolant flow path 322C so as to allow the coolant to flow therethrough. The second coolant discharge pipe 222 is connected to the coolant flow path 312C so as to allow the coolant to flow therethrough.

Accordingly, the coolant discharged from the flow path outlet 162c is supplied to the inlet port of the chiller 161 via the first coolant discharge pipe 221, the coolant flow path 322C, the internal space 336C of the second bellows 335C, the coolant flow path 312C, and the second coolant discharge pipe 222.

The third bellows 340C is disposed on the outer side of the second bellows 335C. The third bellows 340C has a tubular shape and is configured to be expandable and contractible. One end of the third bellows 340C is hermetically connected to the first member 310C by welding or the like, and the other end of the third bellows 340C is hermetically connected to the second member 320C by welding or the like. An internal space 341C located inside the third bellows 340C and outside the second bellows 335C is connected to the gas flow path 313C so as to allow a gas to flow therethrough.

The dry air supply source 167 fills the internal space 341C with dry air via the gas flow path 313C. In FIG. 7, the internal space 341C filled with dry air is shown with dot hatching. Further, the pressure detection chamber 168 having the pressure sensor 169 is provided between the dry air supply source 167 and the gas flow path 313C. The pressure sensor 169 detects the pressure of the internal space 341C by detecting the pressure inside the pressure detection chamber 168.

The internal space 331C of the first bellows 330C allows the supply coolant to flow therethrough. The internal space 336C located outside the first bellows 330C and inside the second bellows 335C allows the return coolant to flow therethrough. The internal space 341C located outside the second bellows 335C and inside the third bellows 340C, is filled with dry air. The outside of the third bellows 340C corresponds to the internal space 80S of the processing container including the bottom wall 80 and is under vacuum.

As described above, since the expansion and contraction portion 300C is installed in the coolant introduction flow path 210 and the coolant discharge flow path 220, the bellows 330C, 335C, and 340C can be deformed in response to vertical movement of the cooling member 162 supported by the elastic member 166. Accordingly, the cooling member 162 and the cold link 163 may be cooled by circulating the coolant between the chiller 161 and the coolant flow path 162a.

In addition, there is a concern that the bellows 330C, 335C, and 340C of the expansion and contraction portion 300C may be damaged by repeated expansion and contraction.

Here, when the first bellows 330C of the expansion and contraction portion 300C is damaged, the coolant flowing through the internal space 331C leaks into the internal space 336C of the second bellows 335C. As a result, the coolant can be prevented from leaking into the internal space 80S of the processing container.

Further, when the second bellows 335C of the expansion and contraction portion 300C is damaged, the coolant flowing through the internal space 336C leaks into the internal space 341C of the third bellows 340C and then flows into the pressure detection chamber 168 via the gas flow path 313C. As a result, the coolant can be prevented from leaking into the internal space 80S of the processing container.

In addition, the controller 70 detects the pressure of the pressure detection chamber 168 using the pressure sensor 169. Here, damage occurs in the second bellows 335C, the coolant flowing through the internal space 336C leaks into the internal space 341C, so that the pressure detected by the pressure sensor 169 changes. For example, the pressure detected by the pressure sensor 169 increases. The controller 70 can detect damage to the second bellows 335C by detecting a change (e.g., an increase) in the pressure detected by the pressure sensor 169.

Further, when the third bellows 340C of the expansion and contraction portion 300C is damaged, the dry air in the internal space 341C leaks into the internal space 80S of the processing container. Meanwhile, the second bellows 335C is not damaged, and the coolant flowing through the internal space 331C can be prevented from leaking into the internal space 80S of the processing container.

Further, the controller 70 detects the pressure of the pressure detection chamber 168 using the pressure sensor 169. Here, damage occurs in the third bellows 340C, the dry air with which the internal space 341C is filled leaks into the internal space 80S of the processing container, so that the pressure detected by the pressure sensor 169 changes. For example, the pressure detected by the pressure sensor 169 decreases. The controller 70 can detect damage to the third bellows 340C by detecting a change (e.g., a decrease) in the pressure detected by the pressure sensor 169.

While the substrate stages 1, 1A and 1B have been described above, the present disclosure is not limited to the above-described embodiments and the like, and various modifications and improvements can be made within the scope of the gist of the present disclosure as set forth in the claims. For example, the coolant is configured to flow through the internal spaces 331A, 331B, 331C, and 336C. Alternatively or additionally, a heat medium may be circulated.

According to the present disclosure in some embodiments, it is possible to provide a substrate stage and a substrate processing apparatus for cooling a stage.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate stage, comprising:
a stage on which a substrate is placed;
a stage support mechanism configured to support the stage; and
a cooling mechanism configured to cool the stage,
wherein the stage has a contact surface located on a rear surface of the stage and formed radially outward of a support portion of the stage supported by the stage support mechanism, and
wherein the cooling mechanism includes:
a cold link;
a cooler configured to cool the cold link; and
a heat transfer plate provided between the contact surface of the stage and the cold link.

2. The substrate stage of claim 1, wherein the stage support mechanism includes:
a rotation driver configured to rotate the stage; and
an elevation driver configured to raise and lower the stage, and
wherein the elevation driver is configured to switch between a state in which the stage is in contact with the cold link and a state in which the stage is separated from the cold link.

3. The substrate stage of claim 2, wherein the stage support mechanism has a hollow portion, and
wherein a power supply path configured to supply power to an electrode of the stage is disposed in the hollow portion.

4. The substrate stage of claim 1, further comprising an elastic member, which is deformed in a state in which the stage and the cold link are in contact.

5. The substrate stage of claim 4, wherein the elastic member is provided between the cold link and a support member supporting the cold link.

6. The substrate stage of claim 5, wherein the elastic member is a metal bellows disposed between the cold link and the support member.

7. The substrate stage of claim 4, wherein the elastic member is provided in the stage support mechanism.

8. The substrate stage of claim 1, wherein the cooler includes:
a refrigerator; and
a heat transfer member configured to thermally connects the refrigerator and the cold link.

9. The substrate stage of claim 1, wherein the cooler includes:
a chiller configured to supply a cooled coolant;
a cooling member thermally connected to the cold link and including a coolant flow path;
a coolant introduction flow path configured to introduce the coolant from the chiller to an inlet of the coolant flow path; and
a coolant discharge flow path configured to return the coolant from an outlet of the coolant flow path to the chiller.

10. The substrate stage of claim 9, wherein the coolant introduction flow path and the coolant discharge flow path include an expansion and contraction portion.

11. The substrate stage of claim 10, wherein the expansion and contraction portion is installed between a first coolant introduction pipe fixed to a bottom wall of a processing container in which the stage is disposed and a second coolant introduction pipe fixed to the cooling member.

12. The substrate stage of claim 10, wherein the expansion and contraction portion includes:
a first bellows; and
a second bellows disposed outside the first bellows,
wherein the coolant flows through an internal space of the first bellows, and
wherein an internal space between the second bellows and the first bellows is filled with a gas.

13. The substrate stage of claim 10, wherein the expansion and contraction portion includes:
a first bellows;
a second bellows disposed outside the first bellows; and
a third bellows disposed outside the second bellows,
wherein the coolant flows through an internal space of the first bellows,
wherein the coolant flows through an internal space between the second bellows and the first bellows, and
wherein an internal space between the third bellows and the second bellows is filled with a gas.

14. The substrate stage of claim 12, further comprising a pressure sensor configured to detect pressure of the internal space filled with the gas.

15. The substrate stage of claim 1, wherein the contact surface is formed as an annular surface located radially outside the support portion.

16. The substrate stage of claim 1, wherein the cold link has an annular shape disposed radially outside the support portion.

17. The substrate stage of claim 1, wherein the heat transfer plate is selected from soft metals consisting of indium, silver, or tin.

18. A substrate processing apparatus, comprising:
a processing container; and
the substrate stage according to claim 1.

19. The substrate processing apparatus of claim 18, wherein the cooler includes:
a chiller configured to supply a cooled coolant;
a cooling member thermally connected to the cold link and including a coolant flow path;
a coolant introduction flow path configured to introduce the coolant from the chiller to an inlet of the coolant flow path; and
a coolant discharge flow path configured to return the coolant from an outlet of the coolant flow path to the chiller.

20. The substrate processing apparatus of claim 19, wherein at least one of the coolant introduction flow path or the coolant discharge flow path includes an expansion and contraction portion, the expansion and contraction portion being capable of following vertical position changes of the cooling member.
